(19) United States
(12) Patent Application Publication
(10) Pub. No.: US 2014/0109967 A1
(43) Pub. Date: Apr. 24, 2014

(54) THIN FILM SOLAR CELLS FOR WINDOWS BASED ON LOW COST SOLUTION PROCESS AND FABRICATION METHOD THEREOF

(71) Applicant: KOREA INSTITUTE OF SCIENCE AND TECHNOLOGY, Seoul (KR)

(72) Inventors: Byoung Koun MIN, Seoul (KR); Yun Jeong HWANG, Seoul (KR); Sung-Hwan MOON, Daegu (KR); Se Jin PARK, Seoul (KR)

(73) Assignee: KOREA INSTITUTE OF SCIENCE AND TECHNOLOGY, Seoul (KR)

(21) Appl. No.: 14/058,991

(22) Filed: Oct. 21, 2013

(30) Foreign Application Priority Data
Oct. 24, 2012 (KR) 10-2012-0118195
May 13, 2013 (KR) 10-2013-0053727

(51) Int. Cl. H01L 31/18; H01L 31/048

(52) U.S. Cl. CPC H01L 31/1864; H01L 31/048
USPC 136/262; 136/252; 438/57; 438/85

(57) ABSTRACT

Disclosed is a bifacial thin film solar cell that is applicable to a BIPV window, particularly a bifacial CIGS thin film solar cell that can generate electricity by both sunlight and indoor illumination due to its ability to absorb light at both front and rear sides. According to several embodiments, visible light in a particular wavelength region can be transmitted through the semi-transparent thin film solar cell. In addition, high stability and safety of the thin film solar cell can be ensured because there is no need to use organic materials and liquid electrolytes. Furthermore, the fabrication cost of the thin film solar cell can be reduced by a low cost solution process. The thin film solar cell exhibits various other effects described in the specification.

### CROSS-REFERENCE TO RELATED APPLICATIONS

This application claims priority under 35 U.S.C. §119 to Korean Patent Applications 10-2012-0118195 filed on Oct. 24, 2012 and 10-2013-0053727 filed on May 13, 2013, in the Korean Intellectual Property Office, the disclosure of which is incorporated herein by reference in its entirety.

### BACKGROUND OF THE INVENTION

1. Field of the Invention

The present invention relates to bifacial inorganic thin film solar cells fabricated by a low cost solution processing method, and more particularly to chalcopyrite thin film solar cells that can be applied to building-integrated photovoltaic (BIPV) windows due to their semi-transparency.

2. Description of the Related Art

Solar cells can produce electricity directly from sunlight, which is a clean and safe energy source. For this reason, solar cells have attracted considerable attention as the most promising future candidates for energy production. Various kinds of inorganic and organic semiconductors are applied to the fabrication of solar cells. Representative examples of solar cells that have been commercially successful to date include silicon solar cells using silicon (Si) as a main material, and CIGS thin film solar cells. Silicon solar cells have the advantage of high power conversion efficiency but suffer from high fabrication costs. Under such circumstances, thin film solar cells using compound semiconductors that can be formed into thinner films are of growing interest as potential replacements for silicon solar cells.

Chalcopyrite compound thin film solar cells in which CuInₓGa₁₋ₓS_{y}Se_{2-y} (CIGS) film is used as an absorber layer have been considered the most promising alternative to crystalline silicon solar cells. In general, CIGS thin film solar cells have a typical device configuration of ZnO:Al/ZnO/CdS/CIGS/Mo-coated soda-lime glass, namely, opaque substrate-type. In this architecture, sunlight can transmit from only the front side because an opaque Mo layer blocks light introduction from the rear side.

Building-integrated photovoltaic (BIPV) systems are application fields of solar cells whose market is expected to grow rapidly in the future. Particularly, solar cell windows are recognized as next-generation solar cell applications where both high transmittance and high generation efficiency are required. Dye-sensitized solar cells (DSSCs) are currently known as solar cells that have potential applications in BIPV windows. DSSCs are suitable for use in BIPV windows in that the transmittance of electricity generating parts is controllable and colors or images can be introduced through control over the dispersibility of n-type semiconductor nanoparticles and the thickness of films. However, stability problems encountered with DSSCs remain unsolved. Stability is the most fundamental requirement of solar cells. It is thus anticipated that much time will be needed to put DSSCs to practical use. Further, DSSCs use liquid electrolytes that are very toxic to humans. The toxic substances are liable to leak upon damage, which may also cause serious safety problems.

In contrast, inorganic thin film solar cells designed to be semi-transparent can be used for the manufacture of BIPV windows that are superior in terms of stability and safety while ensuring daylighting. Bifacial CIGS thin film solar cells using transparent glass substrates have already been reported, but thin film solar cells having light transmission characteristics sufficient to be applicable to BIPV windows have not yet been reported. Particularly, no research has been conducted on semi-transparent, bifacial thin film solar cells that are capable of generating electricity simultaneously by sunlight at one side and by indoor illumination at the other side.

### SUMMARY OF THE INVENTION

Several embodiments of the present invention provide bifacial inorganic thin film solar cells that are fabricated based on a low cost solution process and are applicable to light transmissible BIPV windows due to their semi-transparency.

According to one aspect of the present invention, there is provided a thin film solar cell for a window, including (a) a transparent conducting substrate, (b) a solution processed absorber layer having a band-gap of at least 1.5 eV formed on the transparent conducting substrate, (c) a buffer layer formed on the absorber layer, (d) a window layer disposed on the buffer layer, and (e) a metal electrode disposed on the window layer.

As mentioned above, the bifacial inorganic thin film solar cell can generate electricity simultaneously by sunlight and indoor illumination due to its ability to absorb light at both front and rear sides. In addition, the bifacial inorganic thin film solar cell is semi-transparent. Particularly, high safety and stability of the bifacial inorganic thin film solar cell are ensured because there is no need to use liquid electrolytes and organic materials. Due to these advantages, the bifacial inorganic thin film solar cell can be applied to BIPV windows and exhibits various other effects described in the specification.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram showing simultaneous generation of electricity from a semi-transparent, bifacial thin film solar cell for a window by outdoor sunlight and indoor illumination;

FIG. 2 shows the structure of a semi-transparent, bifacial thin film solar cell and the semi-transparency of completed devices with absorber films of different thicknesses;

FIG. 3 shows a completed solar cell device showing the transparency of a solar cell with an 800 nm thick film and a UV-Vis spectrum showing the transmittance of the solar cell; and

FIG. 4 shows UV-Vis spectra showing the transmittances of solar cells with 400 nm thick films depending on the proportion of Ga and comparing visible light transmittances of the solar cells depending on the element proportion.

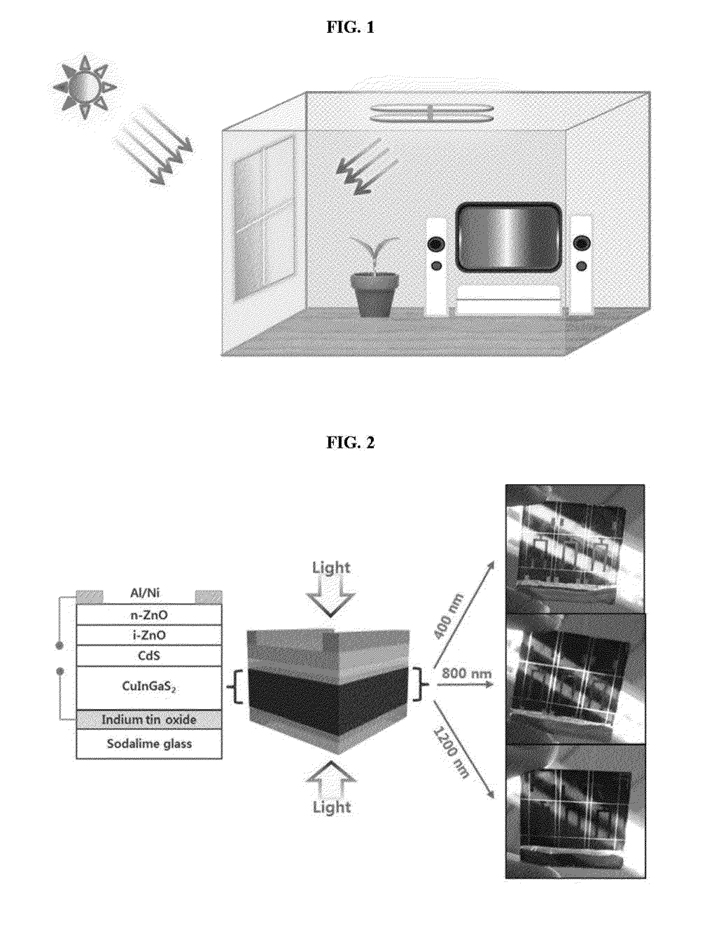

### DETAILED DESCRIPTION OF THE INVENTION

The present invention will now be described in detail.

In order to fabricate bifacial inorganic thin film solar cells for windows that are semi-transparent and can generate electricity at both sides by sunlight, absorber films should have band-gaps of at least 1.5 eV, at which a portion of light in the visible region can be transmitted through the absorber films, and small thicknesses. The presence of a larger number of pores in the thin films ensures better light transmission characteristics.

In one aspect, the present invention provides a thin film solar cell for a window, including (a) a transparent conducting substrate, (b) an absorber layer formed on the transparent conducting substrate, (c) a buffer layer formed on the absorber layer, (d) a window layer disposed on the buffer layer, and (e) an electrode disposed on the window layer, wherein the absorber layer is formed by a solution processing method; the absorber layer has a band-gap of 1.5 eV or more, 1.5 to 10 eV, 1.5 to 7.5 eV, or 1.5 to 5 eV; the absorber layer has a thickness of 1,000 nm or less, preferably 200 to 1,000 nm; and the thin film solar cell has an average transmittance of 10 to 20% in the wavelength range of 600 to 750 nm, as determined by UV-Vis spectroscopy.

That is, the absorber layer of the bifacial thin film solar cell is formed into a thin film having a high band-gap on a transparent conducting substrate, so that a predetermined amount of visible light can be transmitted through the bifacial thin film solar cell and light irradiated on both sides of the bifacial thin film solar cell can be efficiently used. Particularly, the formation of the absorber layer by a solution processing method enables low cost fabrication of the bifacial thin film solar cell. Particularly, particles present in the absorber film formed by a solution processing method are small in size and have a strong tendency to form pores. Due to this structure, the light transmission performance of the bifacial thin film solar cell is improved and the bifacial illumination results in an extra increase of the power conversion efficiency compared to the simple sum of the efficiencies of front and rear side illumination only, which will be discussed in detail hereinafter.

In one embodiment, the absorber layer of the thin film solar cell is composed of CuInₓGa₍₁₋ₓ₎S_{y}Se_{(2-y)} where x is a real number of 0 to 1 and y is a real number of 0 to 2.

The band-gap of the absorber layer can be tuned by varying the composition of the elements constituting the thin film. Depending on the tunable band-gap, the visible light transmittance of the absorber layer can be controlled. For example, the absorber film composed of CIGS with a composition ratio of 1:0.7:0.3:2 (Cu:In:Ga:S) has a band-gap of 1.5 eV. In this case, about 10% of visible light in a particular wavelength region can be transmitted through the absorber film. Meanwhile, the absorber film composed of CIGS with a composition ratio of 1:0.5:0.5:2 (Cu:In:Ga:S) has a band-gap of 1.7 eV. In this case, about 20% of visible light in a particular wavelength region can be transmitted through the absorber film. As the band-gap of the absorber layer increases, the transparency and transmittance of the absorber layer are improved but the absorbance of the solar cell is deteriorated, resulting in low efficiency of the solar cell. Likewise, as the number of pores present in the thin film increases, the light transmission characteristics of the thin film are improved but the efficiency of the solar cell is decreased. Therefore, it is preferred to optimize the absorber film in terms of both light transmittance and solar cell efficiency.

The conversion efficiencies of the bifacial thin film solar cell for front and rear side illumination vary depending on the thin film thickness of the absorber layer. Higher efficiency is exhibited at a larger thickness of the absorber layer for front side illumination, while the highest solar cell efficiency is exhibited at an optimum thickness of the absorber layer for rear side illumination. Therefore, since sunlight is irradiated on both sides of the bifacial solar cell, the highest efficiency is exhibited at a particular thickness of the absorber layer. Preferably, the overall power conversion efficiency of the bifacial solar cell is highest when the absorber layer is about 800 nm thick. In light of the fact that an absorber layer of a general CIGS thin film solar cell is formed to a thickness of about 2.000 nm on an opaque substrate, the bifacial thin film solar cell of the present invention has the advantage that better effects can be attained despite the use of much smaller amounts of material.

It should be understood that the thickness of the absorber layer of the bifacial solar cell according to the present invention does not indicate the corresponding exact value only and includes approximate values within the permissible range in the art. For example, the 800 nm thick absorber layer means that the absorber layer not only has an average thickness of exactly 800 nm, but also has a thickness in the range of, for example, 800 nm±20%, preferably 800 nm±10%. The above-mentioned effects can be maximized when the approximation range is smaller.

The conducting substrate may be made of at least one material selected from indium tin oxide, fluorine-doped indium tin oxide, glass, graphene, and transparent conducting polymers. A non-conducting substrate coated with at least one material selected from indium tin oxide, fluorine-doped indium tin oxide, glass, and transparent conducting polymers may also be used as the conducting substrate.

In one embodiment of the present invention, the solution processing method includes (a) dissolving a metal precursor and an organic binder in a solvent to obtain a precursor paste, (b) coating the precursor paste on the transparent conducting substrate, (c) annealing the transparent conducting substrate coated with the precursor paste in air or an oxygen gas atmosphere to obtain a metal oxide thin film, and (d) annealing the metal oxide thin film in a sulfur gas, a selenium gas or a sulfur/selenium mixed gas atmosphere to obtain a sulfurized or selenized metal oxide thin film.

In a further embodiment, the solvent may be selected from water, alcohol, acetone, and mixtures thereof, and the organic binder may be selected from ethyl cellulose, polyvinyl acetate, palmitic acid, polyethylene glycol, polypropylene glycol, polypropylene carbonate, propyl enediol, and mixtures thereof.

In a further embodiment, the metal precursor is preferably a mixture of a Cu precursor, an In precursor and a Ga precursor, and the sulfurized or selenized metal oxide thin film is preferably a CIGS thin film.

In one embodiment of the present invention, the solution processing method includes (a) mixing a first metal precursor, a first organic binder, and a first water-soluble solvent to obtain a first paste, (b) mixing a second metal precursor, a second organic hinder, and a second water-soluble solvent to obtain a second paste, (c) coating the first paste on the conducting substrate to form a first paste layer, (d) coating the second paste on the first paste layer to faun a second paste layer, (e) annealing the coated conducting substrate in air or an oxygen atmosphere to obtain a mixed oxide thin film, and (f) annealing the mixed oxide thin film in a sulfur gas, a selenium gas or a sulfur/selenium mixed gas atmosphere to obtain a sulfide or selenide thin film.

The first metal precursor and the second metal precursor, which may be identical to or different from each other, may be each independently a precursor of one or more Group IB metals, a precursor of one or more Group IIIA metals, or a mixture thereof. The precursor of one or more Group IB metals and the precursor of one or more Group IIIA metals may be each independently included in either the first metal precursor or the second metal precursor or both of them.

In a further embodiment of the present invention, the solution processing method includes (a) mixing first metal precursors, a first organic binder, and a first water-soluble solvent to obtain a first paste, (b) mixing second metal precursors, a second organic binder, and a second water-soluble solvent to obtain a second paste, (c) coating the first paste on the conducting substrate to form a first paste layer, (d) coating the second paste on the first paste layer to form a second paste layer, (e) annealing the coated conducting substrate in air or an oxygen atmosphere to obtain a CIG mixed oxide thin film, and (f) annealing the CIG mixed oxide thin film in a sulfur gas, a selenium gas or a sulfur/selenium mixed gas atmosphere to obtain a CIGS thin film.

The first metal precursors and the second metal precursors, which may be identical to or different from each other, may be each independently two or more kinds of precursors selected from Cu, In and Ga precursors. The Cu, In and Ga precursors may be each independently included in either the first metal precursors or the second metal precursors or both of them.

In another further embodiment, the first water-soluble solvent and the second water-soluble solvent, which may be identical to or different from each other, may be each independently selected from water, alcohol, acetone, and mixtures thereof. The first organic binder and the second organic binder, which may be identical to or different from each other, may be each independently selected from ethyl cellulose, polyvinyl acetate, palmitic acid, polyethylene glycol, polypropylene glycol, polypropylene carbonate, propylenediol, and mixtures thereof.

In another embodiment, the conducting substrate may be made of at least one material selected from indium tin oxide, fluorine-doped indium tin oxide, glass, graphene, and transparent conducting polymers. A non-conducting substrate coated with at least one material selected from indium tin oxide, fluorine-doped indium tin oxide, glass, and transparent conducting polymers may also be used as the conducting substrate.

Although the solution processing method used in the present invention has been described with reference to the foregoing embodiments, it is not limited to the embodiments. The solution processing method is intended to include conventional low cost solution coating methods for producing CIS absorber films using inks of CIS nanoparticles and inks or pastes of CIS precursors other than the methods mentioned in the above embodiments.

Specifically, the solution processing method may be selected from printing methods using inks of CIS nanoparticles or inks of CIS precursors, for example, doctor blade coating, screen printing, spin coating, ink-jet printing, and combinations thereof.

In one embodiment, the absorber layer has a thickness of N×(200±20) nm where N is a natural number of 1 to 10.

In a further embodiment, the thickness of the absorber layer is selected from 400±20 nm, 800±20 nm, and 1,200±20 nm.

In another embodiment, the absorber layer may be divided into at least two absorber layers including a first absorber layer and a second absorber layer. In this embodiment, the thicknesses of the first absorber layer and the second absorber layer may be identical to or different from each other and are each independently N×(200±20) nm where N is a natural number of 1 to 10.

In another embodiment, the thicknesses of the first absorber layer and the second absorber layer may be identical to or different from each other and are each independently selected from 400±20 nm, 800±20 nm, and 1,200±20 nm.

In a further aspect, the present invention provides a method for controlling the band-gap of a photoactive layer of a thin film solar cell, wherein the thin film solar cell includes (a) a transparent conducting substrate, (b) an absorber layer formed on the transparent conducting substrate, and (c) a buffer layer formed on the absorber layer, (d) a window layer disposed on the buffer layer, and (e) an electrode disposed on the window layer; the absorber layer is formed by a solution processing method; and the absorber layer is composed of CuInₓGa₍₁₋ₓ₎S_{y}Se_{(2-y)} (where x is a real number of 0 to 1 and y is a real number of 0 to 2), the method including varying the ratio of In/Ga in the absorber layer to control the band-gap.

In another aspect, the present invention provides a method for controlling the transmittance of a photoactive layer of a thin film solar cell, wherein the thin film solar cell includes (a) a transparent conducting substrate, (b) an absorber layer formed on the transparent conducting substrate, and (c) a buffer layer formed on the absorber layer, (d) a window layer disposed on the buffer layer, and (e) an electrode disposed on the window layer; the absorber layer is formed by a solution processing method; and the absorber layer is composed of CuInₓGa₍₁₋ₓ₎S_{y}Se_{(2-y)} (where x is a real number of 0 to 1 and y is a real number of 0 to 2), the method including varying the ratio of In/Ga in the absorber layer to control the transmittance.

In an embodiment of both aspects, the absorber layer has a band-gap of 1.5 to 10 eV, 1.5 to 7.5 eV, or 1.5 to 5 eV.

In a further embodiment, the absorber layer has a thickness of 1,000 nm or less, preferably 200 to 1,000 nm.

In another embodiment, the thin film solar cell has an average transmittance of 10 to 20% in the wavelength range of 600 to 750 nm, as determined by UV-Vis spectroscopy.

In another embodiment, the thin film solar cell is applied to a window.

In yet another aspect, the present invention provides a window including any one of the thin film solar cells according to the embodiments of the present invention.

The present invention will be explained in more detail with reference to the following examples. However, these examples are not to be construed as limiting or restricting the scope and spirit of the invention. It is to be understood that based on the teachings of the present invention including the following examples, those skilled in the art can readily practice other embodiments of the present invention whose specific experimental data are not available.

### EXAMPLES

In order to fabricate CIGS thin films more cost effectively, solution based printing methods are more desirable because they have advantages such as low processing capital costs, efficient resource material usage, high throughput, etc. To achieve bifacial CIGS thin film solar cells by a low cost and printable way, a fabrication method similar to that of CIGS thin film on Mo coated glass was applied to the substrate of transparent conducting oxide (ITO) glass.

CIGS absorber layers having high band-gaps (≧1.5 eV) and small thicknesses of 1 μm or less were produced to ensure high transparency and transmittance of solar cells. The band-gaps of the CIGS absorber layers were tuned by varying the elemental composition.

### Example 1

### Fabrication of Solution Processed Bifacial Thin Film Solar Cell

A CIGS absorber film was produced by the following procedure. First, a precursor mixture solution was prepared by dissolving Cu(NO₃)₂.xH₂O (99.999%, Alfa Aesar, 1.0 g), In(NO₃)₃.xH₂O (99.99%, Alfa Aesar, 1.12 g), and Ga(NO₃)₃.xH₂O (99.999%, Alfa Aesar, 0.41 g) in methanol (7.0 ml), followed by adding of a methanol solution (7.0 ml) with PVA (Aldrich, 1.0 g). After the mixture solution was stirred for 30 min, a paste suitable for spin coating was prepared. The paste was spin-casted on an ITO glass substrate (Samsung Corning, ˜8Ω/□), and the film was dried on a hotplate at 150° C. for 3 min and subsequently at 250° C. for 7 min. To obtain the desired thickness of the film, the above process was repeated. ˜200 nm thick film was obtained for each deposition.

After coating and drying, the first annealing process, air annealing, was performed at 300° C. for 30 min under ambient conditions. The second annealing process, sulfurization, was carried out at 500° C. for 30 min under H₂S (1%)/N₂ gas environment.

A solar cell device was fabricated according to the substrate type configuration (ZnO:Al/i-ZnO/CdS/CIGS/ITO glass). A 60 nm-thick CdS buffer layer was prepared on the CIGS film by chemical bath deposition (CBD), and i-ZnO (50 nm)/Al-doped n-ZnO (500 nm) was deposited by the radio frequency magnetron sputtering method. A Ni/Al (50/500 nm) grid was prepared as a current collector by thermal evaporation. The active area of the completed cell was 0.44 cm².

Structural characterization of the films was performed using a scanning electron microscope (SEM, FEI, Nova-Nano200) with a 10 kV acceleration voltage and an X-ray diffractometer (XRD, Shimadzu, XRD-6000) with Cu—Kα radiation (λ=0.15406 nm). The film thickness was measured with a surface profiler (Veeco, Dektak 8). Device performances were characterized using a solar simulator (Sun 2000, ABET Technologies, Inc.) and an incident photon-to-current conversion efficiency (IPCE) measurement unit (PV measurement Inc.). During the IPCE measurement, background light (LED, Daejin DMP Co.) was applied.

Bifacial solar cell devices were constructed using the CIGS thin films of three different thickness based on substrate-type configuration (ZnO:Al/i-ZnO/CdS/CIGS/ITO glass). General deposition recipes were also applied for a CdS buffer layer (chemical bath deposition) and a ZnO window layer (sputtering deposition). The efficiency characteristics of the completed solar cell devices are shown in Table 1. Both open circuit voltage (Voc) and short circuit current density (Jsc) were found to increase as the film thickness increased (see Table 1). The highest power conversion efficiency, therefore, was obtained by the device with a 1200 nm thick CIGS film, which showed the best power conversion efficiency of 5.61%. On the other hand, for rear side illumination, different J-V behaviors were seen in which the highest efficiency was found in the device with the 800 nm thick CIGS film (1.01%).

TABLE 1
Solar cell performance results of bifacial solar cell devices
with different levels of CIGS film thickness

| CIGS film | Illumination | | J_{sc} | | |
|---|---|---|---|---|---|
| thickness (nm) | side | V_{oc} (V) | (mA/cm²) | FF (%) | Eff. (%) |
| 400 | Bifacial | 0.516 | 13.2 | 44.7 | 3.03 |
| | Front only | 0.495 | 8.86 | 40.8 | 1.70 |
| | Rear only | 0.458 | 3.81 | 42.5 | 0.74 |
| 800 | Bifacial | 0.624 | 19.9 | 43.8 | 5.45 |
| | Front only | 0.634 | 15.1 | 41.5 | 3.98 |
| | Rear only | 0.557 | 3.60 | 50.3 | 1.01 |
| 1200 | Bifacial | 0.665 | 17.6 | 53.9 | 6.37 |
| | Front only | 0.680 | 15.5 | 54.1 | 5.61 |
| | Rear only | 0.580 | 1.86 | 61.7 | 0.62 |

The reason why the solar cell device with the thickest film resulted in the highest efficiency for front side illumination is that the most efficient light absorption occurred in the film. However, for rear side illumination, photo-generated electrons and holes in the thicker film have to travel a much longer distance before they arrive at the junction formed at the interface between the CdS buffer layer and the CIGS absorber layer, leading to higher recombination probability. This recombination causes loss of the electrons and holes and results in a low efficiency of the thicker film.

Interestingly, the efficiencies of bifacial illumination are slightly higher than the simple sum of only the front and rear side illumination, implying the presence of synergistic effects in the bifacial solar cell configuration. As can be seen in Table 1, the highest enhancement was observed in the device with the 800 nm thick CIGS film, while the lowest enhancement was found in the device with the 1200 nm thick CIGS film. These trends seem to be similar to those of the power conversion efficiency of the rear side illumination for the same device.

### Example 2

### Simultaneous Generation of Electricity from Bifacial Solar Cells by Sunlight and Indoor Illumination (Weak Light)

In order to measure the power conversion efficiencies of the bifacial solar cells constructed using the CIGS thin films of three different thicknesses based on substrate-type configuration (ZnO:Al/ZnO/CdS/CIGS/ITO glass) by sunlight and indoor illumination, the bifacial solar cells were irradiated with solar simulators of differently set intensities. The power conversion efficiencies of a standard Si solar cell were measured by irradiating 100% intensity of 1 Sun on the front side where sunlight is irradiated and irradiating 30% (weak light) intensity of 1 Sun on the rear side where indoor illumination is irradiated. As a result, the efficiencies of the bifacial illumination for all of the solar cells with the 400, 800 and 1200 nm thick films were increased compared to the efficiencies of the front side illumination only, and the largest increase was observed in the solar cell with the 800 nm thick film (see Table 2).

Thus, the bifacial window type thin film solar cells generated electricity at the front sides by strong sunlight. Further, the electricity generation efficiencies of the solar cells were increased by indoor illumination of relatively weak light irradiated on the rear sides. Therefore, the window type solar cells are of great value in that both sides can be used for simultaneous electricity generation.

TABLE 2
Performance of bifacial solar cells upon sunlight irradiation
and indoor illumination

| CIGS film | Illumination side | Illumination side |
|---|---|---|
| thickness | (light intensity %) | (light intensity %) |
| (nm) | Eff (%) | Eff (%) |
| 400 | Front (100%) 1.70 | Bifacial [front (100%) + |
| | | rear (30%)] 1.80 |
| 800 | Front (100%) 3.98 | Bifacial [front (100%) + |
| | | rear (30%)] 4.23 |
| 1200 | Front (100%) 5.61 | Bifacial [front (100%) + |
| | | rear (30%)] 5.82 |

### Example 3

### Light Transmission Characteristics Depending on Elemental Composition of Absorber Films

Thin films whose composition ratios of Cu:In:Ga:S were changed from 1:0.7:0.3:2 to 1:0.5:0.5:2 and 1:0.3:0.7:2 to investigate the light transmission characteristics of solar cells depending on the elemental composition. Further, three CIGS absorber films with different thicknesses (400 nm, 800 nm, and 1,200 nm) were produced to investigate the performance of solar cells depending on the thicknesses.

Specifically, the In proportions were reduced to 0.5 and 0.3 and the Ga proportions were increased 0.5 and 0.7 to increase the transmittances of the absorber films depending on the elemental composition. First, a precursor mixture solution was prepared by dissolving Cu(NO₃)₂.xH₂O (99.999%, Alfa Aesar, 1.0 g), In(NO₃)₃.xH₂O (99.99%, Alfa Aesar, 0.8 g, 0.48 g), and Ga(NO₃)₃.xH₂O (99.999%, Alfa Aesar, 0.68, 0.96 g) in methanol (7.0 ml), followed by adding of a methanol solution (7.0 ml) with PVA (Aldrich, 1.0 g). After the mixture solution was stirred for 30 min, a paste suitable for spin coating was prepared. The subsequent processes, including coating, annealing, and solar cell device fabrication, were carried out in the same manner as in Example 1.

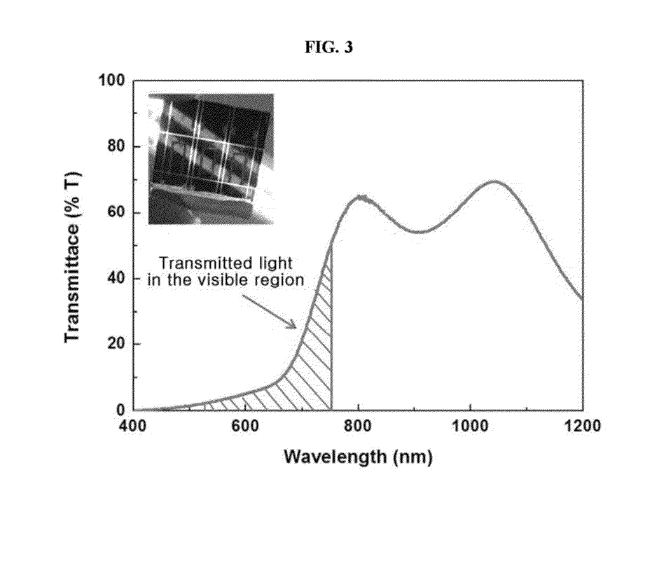

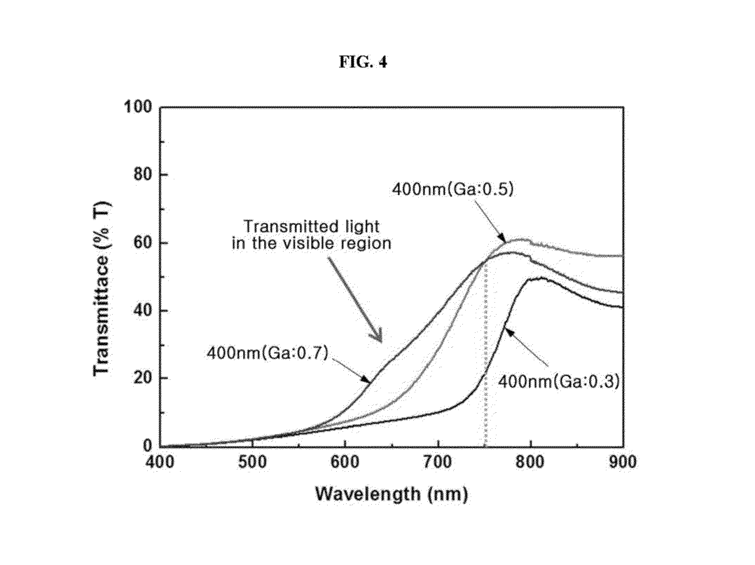

The semi-transparency of the solar cells depending on the thickness of the absorber films could be visually observed in FIG. 2. For more accurate transmittances, FUV-Vis spectroscopy measurement was done using a spectrometer (Carry5000, Varian). As can be seen from FIG. 2, the solar cells with the thin films having different thicknesses and varying Ga proportions were illuminated with fluorescent lamps, and their transmittances were observed. As a result, the transmittances were increased with decreasing thin film thickness. As can be seen from FIG. 3, when the thin film thickness was 800 nm, a transmittance of an average of 20% or more was observed in the wavelength range of 650 to 750 nm. FIG. 4 shows a markedly increased transmittance of the solar cell with the increased Ga proportion.

As discussed above, the solution processed chalcopyrite compound film (CuInGaS₂, CIGS) was synthesized on the transparent conducting oxide substrates (tin-doped indium oxide, ITO) aiming at fabrication of the bifacial inorganic thin film solar cells by a low cost and printable method. Simple paste coating method was applied to prepare the CIGS thin films using the alcohol based precursor solution under ambient conditions followed by two step heat treatment process (oxidation and sulfurization). According to the solar cell performance of the CIGS solar cell devices with the CIGS thin films of three different thicknesses (400, 800, and 1200 nm), the solar cell device with the thickest film (1200 nm) resulted in the highest power conversion efficiency for front side illumination (5.61%) while the 800 nm thick film revealed the best solar to electricity conversion performance for rear side illumination (1.01%). The generation of electricity at both front and rear sides of the solar cell devices by sunlight and weak light simulating indoor illumination was tested with two solar simulators. For this test, the front and rear sides of each bifacial device were irradiated simultaneously with light with the same intensity as sunlight and light with controlled intensity, respectively. Compared to the efficiency of the front side illumination only, the rear side illumination with light having an intensity corresponding to about 30% of sunlight resulted in an increase of efficiency. The highest enhancement was observed in the solar cell with the 800 nm thick film. Further, the light transmission characteristics of the bifacial solar cells depending on the elemental composition of the absorber films were investigated to determine the applicability of the bifacial solar cells to windows. It was confirmed that the increased Ga proportion led to an increase of the band-gap while improving the visible light transmission characteristics.

1. A thin film solar cell for a window, comprising (a) a transparent conducting substrate, (b) an absorber layer formed on the transparent conducting substrate, (c) a buffer layer formed on the absorber layer, (d) a window layer disposed on the buffer layer, and (e) an electrode disposed on the window layer,
wherein the absorber layer is formed by a solution method;
the absorber layer has a band-gap of at least 1.5 eV;
the absorber layer has a thickness of 1,000 nm or less; and
the thin film solar cell has an average transmittance of 10 to 20% in the wavelength range of 600 to 750 nm, as determined by UV-Vis spectroscopy.

2. The thin film solar cell according to claim 1, wherein the band-gap is controlled by varying the ratio of In/Ga in the absorber layer.

3. The thin film solar cell according to claim 2, wherein the absorber layer is composed of CuInₓGa₍₁₋ₓ₎S_{y}Se_{(2-y)} where x is a real number of 0 to 1 and y is a real number of 0 to 2.

4. The thin film solar cell according to claim 3, wherein the solution method uses inks of CIS nanoparticles or inks of CIS precursors and is selected from printing, doctor blade coating, screen printing, spin coating, ink-jet printing, and combinations thereof.

5. A method of preparing a thin film solar cell, wherein the method comprises
(a) dissolving a metal precursor and an organic binder in a solvent to obtain a precursor paste,
(b) coating the precursor paste on the transparent conducting substrate,
(c) annealing the transparent conducting substrate coated with the precursor paste in air or an oxygen gas atmosphere to obtain a metal oxide thin film, and
(d) annealing the metal oxide thin film in a sulfur gas, a selenium gas or a sulfur/selenium mixed gas atmosphere to obtain a sulfurized or selenized metal oxide thin film.

6. The method of preparing a thin film solar cell according to claim 5, wherein the solvent is selected from water, alcohol, acetone, and mixtures thereof, and the organic binder is selected from ethyl cellulose, polyvinyl acetate, palmitic acid, polyethylene glycol, polypropylene glycol, polypropylene carbonate, propylenediol, and mixtures thereof.

7. The method of preparing a thin film solar cell according to claim 6, wherein the metal precursor is a mixture of a Cu precursor, an In precursor and a Ga precursor, and the sulfurized or selenized metal oxide thin film is a CIGS thin film.

8. A method of preparing a thin film solar cell, wherein the method comprises
(a) mixing a first metal precursor, a first organic binder, and a first water-soluble solvent to obtain a first paste,
(b) mixing a second metal precursor, a second organic binder, and a second water-soluble solvent to obtain a second paste,
(c) coating the first paste on the conducting substrate to form a first paste layer,
(d) coating the second paste on the first paste layer to form a second paste layer,
(e) annealing the coated conducting substrate in air or an oxygen atmosphere to obtain a mixed oxide thin film, and
(f) annealing the mixed oxide thin film in a sulfur gas, a selenium gas or a sulfur/selenium mixed gas atmosphere to obtain a sulfide or selenide thin film,
wherein the first metal precursor and the second metal precursor are identical to or different from each other and are each independently a precursor of one or more Group IB metals, a precursor of one or more Group IIIA metals, or a mixture thereof; and the precursor of one or more Group IB metals and the precursor of one or more Group IIIA metals are each independently included in either the first metal precursor or the second metal precursor or both of them.

9. A method of preparing a thin film solar cell, wherein the method comprises
(a) mixing first metal precursors, a first organic binder, and a first water-soluble solvent to obtain a first paste,
(b) mixing second metal precursors, a second organic binder, and a second water-soluble solvent to obtain a second paste,
(c) coating the first paste on the conducting substrate to form a first paste layer,
(d) coating the second paste on the first paste layer to form a second paste layer,
(e) annealing the coated conducting substrate in air or an oxygen atmosphere to obtain a CIG mixed oxide thin film, and
(f) annealing the CIG mixed oxide thin film in a sulfur gas, a selenium gas or a sulfur/selenium mixed gas atmosphere to obtain a CIGS thin film,
wherein the first metal precursors and the second metal precursors are identical to or different from each other and are each independently two or more kinds of precursors selected from Cu, In and Ga precursors; and the Cu, In and Ga precursors are each independently included in either the first metal precursors or the second metal precursors or both of them.

10. The method of preparing a thin film solar cell according to claim 9, wherein the first water-soluble solvent and the second water-soluble solvent are identical to or different from each other and are each independently selected from water, alcohol, acetone, and mixtures thereof, and
the first organic binder and the second organic binder are identical to or different from each other and are each independently selected from ethyl cellulose, polyvinyl acetate, palmitic acid, polyethylene glycol, polypropylene glycol, polypropylene carbonate, propylenediol, and mixtures thereof.

11. The method of preparing a thin film solar cell according to claim 9, wherein the conducting substrate is made of at least one material selected from indium tin oxide, fluorine-doped indium tin oxide, glass, graphene, and transparent conducting polymers, or is a non-conducting substrate coated with at least one material selected from indium tin oxide, fluorine-doped indium tin oxide, glass, and transparent conducting polymers.

12. The thin film solar cell according to claim 4, wherein the absorber layer has a thickness of N×(200±20) nm where N is a natural number of 1 to 10.

13. The thin film solar cell according to claim 12, wherein the thickness of the absorber layer is selected from 400±20 nm, 800±20 nm, and 1,200±20 nm.

14. The thin film solar cell according to claim 4, wherein the absorber layer is divided into at least two absorber layers comprising a first absorber layer and a second absorber layer, and the thicknesses of the first absorber layer and the second absorber layer are identical to or different from each other and are each independently N×(200±20) nm where N is a natural number of 1 to 10.

15. The thin film solar cell according to claim 12, wherein the thicknesses of the first absorber layer and the second absorber layer are identical to or different from each other and are each independently selected from 400±20 nm, 800±20 nm, and 1,200±20 nm.

16. A method for controlling the band-gap of a photoactive layer of a thin film solar cell,
wherein the thin film solar cell comprises (a) a transparent conducting substrate, (b) an absorber layer formed on the transparent conducting substrate, and (c) a buffer layer formed on the absorber layer, (d) a window layer disposed on the buffer layer, and (e) an electrode disposed on the window layer;
the absorber layer is formed by a solution method; and
the absorber layer is composed of CuInₓGa₍₁₋ₓ₎S_{y}Se_{(2-y)} (where x is a real number of 0 to 1 and y is a real number of 0 to 2),
the method comprising varying the ratio of In/Ga in the absorber layer to control the band-gap.

17. A method for controlling the transmittance of a photoactive layer of a thin film solar cell,
wherein the thin film solar cell comprises (a) a transparent conducting substrate, (b) an absorber layer formed on the transparent conducting substrate, and (c) a buffer layer formed on the absorber layer, (d) a window layer disposed on the buffer layer, and (e) an electrode disposed on the window layer;
the absorber layer is formed by a solution method; and
the absorber layer is composed of CuInₓGa₍₁₋ₓ₎S_{y}Se_{(2-y)} (where x is a real number of 0 to 1 and y is a real number of 0 to 2),
the method comprising varying the ratio of In/Ga in the absorber layer to control the transmittance.

18. A window comprising the thin film solar cell according to claim 4.
